(19) United States
(12) Patent Application Publication
(10) Pub. No.: US 2009/0078456 A1
(43) Pub. Date: Mar. 26, 2009

(54) Three dimensional packaging optimized for high frequency circuitry

(76) Inventors: William Macropoulos, Norfolk, MA (US); Izzac Khayo, Nashua, NH (US); Greg Mendolia, Nashua, NH (US)

Correspondence Address: James S. Finn, 2631 Lakeforest Ct, Dallas, TX, 75214, US

(21) Appl. No.: 12/286,012

(22) Filed: Sep. 27, 2008

Related U.S. Application Data
(62) Division of application No. 11/361,513, filed on Feb. 24, 2006.
Application No. 11/361,513 is a continuation-in-part of application No. 11/353,930, filed on Feb. 14, 2006, now Pat. No. 7,471,146.
(60) Provisional application No. 60/653,162, filed on Feb. 15, 2005.

(51) Int. Cl. H01L 21/50; H01R 12/04

(52) U.S. Cl. 174/261; 438/113; 257/E21.499

(57) ABSTRACT

At least an embodiment of the present technology provides a method of manufacturing a mechanically adapting interconnecting device for multi-substrate packages comprising placing a metal laminate on each side of a polymer composite, forming a channel in the metal laminate; and metallizing the laminate to create a metal connection inside the channel.

### CROSS REFERENCE TO RELATED APPLICATION

This application is a divisional of U.S. patent application Ser. No. 11/361,513, entitled, THREE DIMENSIONAL PACKAGING OPTIMIZED FOR HIGH FREQUENCY CIRCUITRY, by Macropoulos, filed Feb. 24, 2006, which is a continuation-in-part of U.S. patent application Ser. No. 11/353,930, filed Feb. 14, 2006, entitled, WIRELESS RF CIRCUITRY OPTIMIZED FOR 3D PACKAGING TECHNOLOGIES, which claimed the benefit of priority under 35 U.S.C Section 119 from U.S. Provisional Application Ser. No. 60/653,162, filed Feb. 15, 2005, entitled, “Wireless RF Circuitry Optimized for 3D Packaging Technologies”.

### BACKGROUND OF THE TECHNOLOGY

Wireless communications is a rapidly growing segment of the communications industry, with the potential to provide high-speed high-quality information exchange between portable devices located anywhere in the world. Potential applications enabled by this technology include multimedia internet-enabled cell phones, smart homes, appliances, automated highway systems, distance learning, and autonomous sensor networks, just to name a few. Supporting these applications using wireless techniques poses significant technical challenge. As handsets move to meet broadband, the requirements of components are more astringent. Battery life has to be maximized, reception clarity in a multitude of environments has to be improved and at the same time the customers require a significant reduction in size. Although the industry has made significant strides in miniaturizing active high frequency components, advancements in packaging of high frequency devices and Surface Mount (SMT) passive components have lagged behind.

Mobile products are getting smaller and integration of components is required to meet this need. As more wireless communications products hit the market, the role of filters is becoming increasingly important. Enhancing the performance of passive high frequency filters along with active components while shrinking size and costs is a must. The industry managed to create design techniques that reduce the number of surface mount components by imbedding Rs, Cs, and Ls and today some of the passives are being integrated into semiconductor die and packaging. However, on-chip passives fabricated using IC semiconductor deposition processes do not deliver sufficient performance and pending on value, integrated on chip passives increase die size and thus cost. Likewise, ceramic technologies such as low temperature co-fired ceramic (LTCC), which uses multiple layers of thin ceramic material are nevertheless difficult to work with and have low high frequency and thermal performance. Although measurable progress has been made in embedding Passive components into polymer and epoxy base substrates large values of Inductor and Capacitance value continues to require large space in multi-layer circuits and interconnectivity between substrate layers increasing substrate complexity and cost.

Contemporary high frequency, RF, analog or mixed signal Packaging requires stringent electrical, mechanical, thermal and environmental performance. For instance, mechanical stress on components, heat dissipation of IC's, moisture resistivity, high frequency performance, they all have to be met simultaneously by the packaged module. In order to get quality high frequency performance of optimized discrete modules, passives must be scaled in size and integrated along active devices to fit the application. Passive components have lower parasitic inductance and capacitance, which is required for higher frequency operations. Today's high frequency modules operate in multiple frequency bands and encounter more interference in a crowded frequency spectrum than ever before. This, along with greater range and battery life demands, mandates superior efficiency of high frequency filters and matching networks. This heavy reliance on analog circuitry requires a large number of passive components to be used. Therefore, the industry solicits a robust single-package solution, where the integration of passives and actives alleviates and accommodates the massive volume of IC's and passive components needed for smaller and lighter products.

### BRIEF DESCRIPTION OF THE SEVERAL VIEWS OF THE DRAWINGS

The foregoing summary, as well as the following detailed description of the technology, will be better understood when read in conjunction with the appended drawings. For the purpose of illustrating the technology, there are shown in the embodiments which are presently preferred. It should be understood, however, that the technology is not limited to the precise arrangements and instrumentalities shown. In the drawings:

FIG. 1 depicts an embodiment of the technology in 3D, where it contains a stack of three different size substrates, one on top of the other separated by SMT passive devices.

FIG. 2 depicts a cross section of an embodiment of the technology, where three substrates are separated and interconnected with SMT passive components and active components in both sides of middle substrate with ball grid array connections.

FIG. 3 depicts a substrate interconnection spacer as part of an embodiment of the technology.

FIG. 4 depicts a method of making said substrate interconnection spacer.

FIG. 5 depicts a cross section of an embodiment of the technology, where three substrates may be connected internally to the middle substrate though a gap.

FIG. 6 A depicts a cross section of a close-up to an embodiment of a passive component as interconnector from the bottom substrate to the middle substrate.

FIG. 6 B depicts a cross section of a close-up to a photograph of a ceramic capacitor as an interconnector from the bottom substrate to the middle substrate.

FIG. 7 depicts an embodiment of the technology in 3D where the inside of the structure is partially covered with a polymer.

FIG. 8 depicts a cross section of an embodiment of the technology, where the IC's mounted on top of two substrates are covered by a glob-top material.

FIG. 9 depicts a cross section of an embodiment of the technology, where it contains a stack of two substrates with land grid array connections.

FIG. 10 depicts a cross section of an embodiment of the technology, where it contains a stack of two substrates with lead frame connections.

FIG. 11 illustrates a distortioned stress model of a single substrate structure depicting when the components inside of the structure are not balanced.

FIG. 12 provides a distortioned 3D stress model structure of a two substrate structure depicting a non balanced structure.

FIG. 13 illustrates a 3D stress model structure depicting when the components inside of the structure are properly balanced.

FIG. 14 illustrates a 2D plane of stress parameters used to develop a properly balanced 3D structure.

### DESCRIPTION OF THE TECHNOLOGY

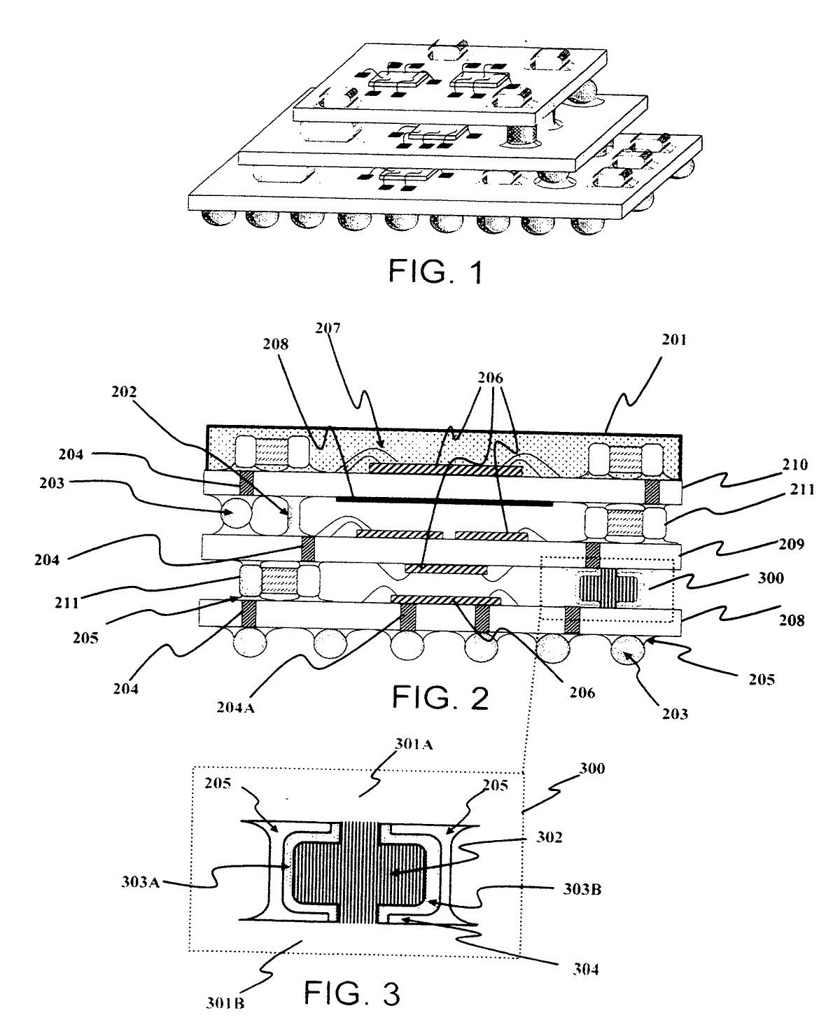

FIG. 1 depicts the overall structure of a 3D stack devise, where three substrates of different size may be stacked on top of each other advantageously attached using SMT components as the principal method of interconnection between the substrates. The FIG. 1 structure may increase device integration and reduce lead and trace lengths and their performance-limiting parasitics. Furthermore, cost reduction is also achieved because the structure formulates device miniaturization and integration. Smaller parts use less material per device and less PC-board real estate, which lowers board costs. At the same time, component integration reduces the number of parts that must be placed on a PWB, thus reducing assembly time. With fewer board-level interconnects, the overall high frequency handset reliability rises thus further lowering costs.

FIG. 1 further depicts how 3D technology integrates passive components into higher-level active components and integrated circuits (IC's), which enables smaller wireless products which are less expensive and more robust. Reductions in discrete package size and integration of passives, shrink device footprints and reduce device heights to satisfy space constraints in portable applications. The flexibility of moving passive components around the multiple substrates in a strategic manner, allows for the device to contour itself to the stringent space restrictions in a cellular phone or any other high frequency mobile handset. It shall be understood to the person skilled in the art that “high frequency” refers to the radio spectrum between 3 MHZ to 30 GHz, which includes both the “RF” spectrum and the “microwave spectrum”. It shall be further understood that a “device” may comprise multiple “components” both “passive components” and “active components” and a “3D” device may comprise of multiple substrates stacked vertically.

Referring to FIG. 2 which depicts a cross section of the technology, where three substrates 208, 210, 209 are separated and interconnected with SMT passive components 211 from the bottom of substrate 208 which uses ball grid array connections 203 to the active components 206 connected to the substrates 208, 209, 210 using wirebonds 207, although the present invention is not limited in this respect. This example shows how advantageously the integrated circuits (IC's) 206 (also referred to herein as semiconductor chips) may be further connected on both sides of middle substrate 209. By connecting passive components to the surface of a substrate heat dissipation may be improved.

Most of the connections between the substrates found in related art technologies are accomplished using either solderballs 203 later reflowed to connect the two surfaces. Another method found in related art is the usage of solder columns 202, where cylinders of solder are disposed between the substrates and later reflowed. There are several disadvantages by using the aforementioned methods as interconnections between substrates. First, creep which is the term given to the material deformation that occurs as a result of long term exposure to levels of stress that are below the yield or ultimate strength. The rate of this damage is a function of the material properties of solder, the exposure time, exposure temperature and the applied load (stress). Creep is usually experienced in solder joints in all types of microelectronic packages when the devices is heated and cooled as a function of use or environmental temperature fluctuations. Such failures can be caused either by direct thermal loads or by electrical resistive loads, which in turn generate excessive localized thermal stresses. Depending on the magnitude of the applied stress and its duration, the deformation may become so large that a solderball 203 may experience brittle and/or ductile fracture, interfacial separation, fatigue crack initiation, propagation, creep, and creep rupture.

Similarly, a solder column 202 may break in a similar manner and no longer perform its function. For example, excessive elastic deformations in slender structures 202 in electronic packages due to overstress loads may sometimes constitute functional failure, such as excessive flexing of interconnection wires, package lids, or flex circuits in electronic devices, causing shorting and/or excessive crosstalk. Other methods used in the related art refer to using the wirebonds 207 as means to interconnect in between IC's. Although, wirebonds are less subjective to creep, long wirebonds cause detrimental parasitic inductance in high frequency circuits due to length of the wires with themselves and to adjacent substrates creating adverse impedance into the circuit. Yet another method found in related art comprise of stacking multiple IC's (back to back-on top of each other) and eliminating the middle substrates. This method reduces the overall height of the 3D stack significantly but has resulted in catastrophic failure due to self-heating. The failure occurs where the heat generating semiconductor junctions lie. By eliminating the substrates, the heat generated in the IC's has no place to travel and self-heating will limit the overall operation of the device.

The present technology eliminates the aforementioned challenges by using two complementary but disjunctive approaches in 3D packaging. The mechanical challenge is resolved by the creation of an interconnector 300. FIG. 3 depicts the cross section of the interconnector 300 which comprises a core made out of layers of dielectric material 303, which are laminated into a composite whole. The dielectric material may usually be comprised or polymers and glass fibers or layers that are sequentially plated with metal 303 and later diced to form the size of a ceramic chip component, although the present invention is not limited in this respect. The interconnector may be picked and placed as a surface mount device on to solder paste 205 and later disposed strategically between the substrates 208, 210,209. One of the advantages of said interconnector 300 is such that the laminated layers may be positioned perpendicular to the shear forces 301A and 301B, although they are not required to be. This allows for the layers to dislocate themselves from its original position due the polymer materials in between the layers, therefore preventing creep and solder deformation in the device due to the thermally induced forces. The layering of a dielectric malleable material becomes a stress reliever, a damper to mechanical vibrations and forces in a thermally oscillating device i.e. elastic deformation in response to mechanical static loads. Although not preferred, it would be equivalent to a person skilled in the art to manufacture such interconnecting device 300 using non-perpendicular laminated dielectric layers for substantially same way and purpose to obtain the same stress damping result.

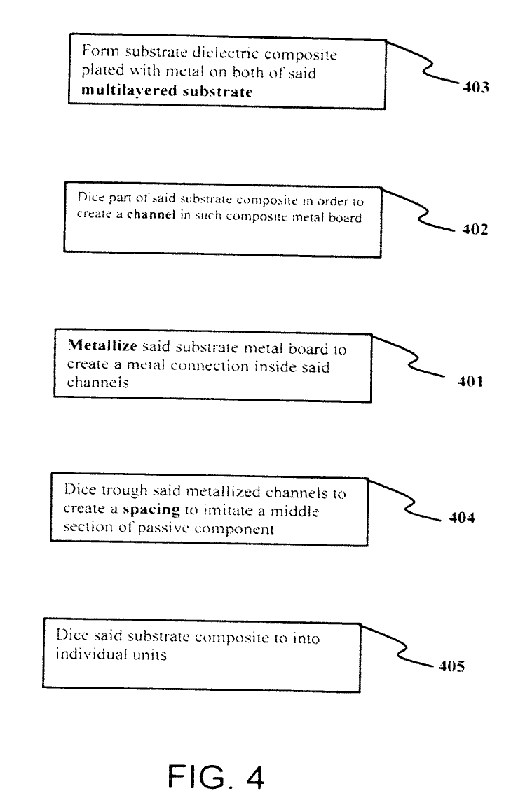

FIG. 4 depicts at least one method of manufacture of an interconnecting device 300 of at least an embodiment of the present technology. It may comprises forming 403 a multilayer dielectric composite by laminating with heat and pressure above the glass transition temperature of a B stage polymer laminate. The sandwich may be composed of two metal laminates 303A and 303 B on both sides of said polymer composite laminate 302. Said laminate 302 may be further diced with an abrasive dicing wheel 402 in order to create groves or channels 304 in said sandwich. The laminate may later metallized or plated 401 in order to create a metal connection inside said channels 304. The laminate may be later diced 404 with an abrasive dicing wheel trough and said metallized channels may create a dielectric spacing to mimic the middle section of passive component. The interconnecting device may be finally diced to mimic the dimensions of a passive component or to the dimension that will give enough space/gap between two substrates to accommodate IC's 206 and other passive components 211. The interconnecting device 300 may also be electrically shorted across 303A and 303 B by either by re-plating 401 the channel 304 or creating a via trough the polymer composite 302.

The electrical challenge in miniaturized or compact 3D packages of high performance, high frequency circuits is low inductance and low parasitic capacitance. This is because the size necessary to withstand significant current and dissipate heat increases inductance and capacitance over smaller low-power active components. Addressing this challenge is relatively easy on a single surface-mount substrate, but it becomes a significant challenge when the device is packaged in a 3D stack. Component and circuit miniaturization also mandates tighter packing of interconnects potentially introducing new parasitic coupling and distributed-element effects into circuits. The inventive approach may comprise the use of passive components 211, chip capacitors, inductors or resistors, as the interconnecting means between the substrates 208, 210, 209.

Examples of substrates for the 3D stack may comprise, but are not limited to: copper clad laminates, thermally stable copper-clad epoxy-glass laminates (FR4), flexible (FLEX) polyimide based substrates such as KAPTON®-DuPont and acrylic base adhesive PARALUX®-DuPont. Said substrate-materials are selected from the group consisting of liquid crystal polymer (LCP), polyolefin, fluropolymers such as polytetrafluorethylene (PTFE), polyvinylidene fluoride (PVDF), polyester products, including terephthalate and polyeylene terephthalate (PET), thermosetting resin bonds are based on the melamine formaldehyde systems and phenol formaldehyde systems. Typical characteristics of these materials comprise: Loss Tangent=0.01 (good in HIGH FREQUENCY) (excellent in analog circuits up to 2.0 ghz and digital circuits above 3.0 ghz) (stable with temperature variations), Er=4.0 to 4.5 (at 1.0 mhz) (specific Er is dependent on glass-to-resin-Er constant from 1.0 mhz to 3.0 ghz), CTEr=+220 ppm per degrees C. (high). Tg is 250 degrees C., Electro-Deposited Copper, Layer-to-layer thickness control=+/−0.002. Similar types of substrates for radio frequency and microwave applications with PCBs may include, but are not limited to, Rogers DURIOD® microwave laminates and teflon materials from manufacturers such as Arlon and DuPont. A ceramic approach has also been investigated and although not the preferred mode may include, but is not limited to, Ceramics such as Alumina (Al2O3), Aluminum Nitride (AlN), glass-ceramic composites such as LTCC, and HTCC.

Passive components (resistors, capacitors, and inductors) acting as connectors from substrate to substrate in a 3D device also may include: filters, diplexers, baluns, resonators and couplers piezoelectrics, and coils. For the disclosed inventive 3D high frequency packages, it is ideal that most of the interconnections be considered as passive components. Passive components have the necessary form factors and performance capabilities for high frequency. Flat frequency response over wideband widths, repeatable performance over time and temperature, good directivity and low insertion loss may be important requirements. Passive components 211 continue to be important elements in RF design, with the same evolving cost and performance demands as active devices. Rather than amplifying signals as active components do, passive components 211 change the characteristics of a signal, letting only the desired frequencies pass through. Passive component manufactures are also moving toward high-temperature plastics and other packaging materials that can withstand the processing temperatures associated with lead-free board assembly. In addition to reducing the physical dimensions, capacitors have had much recent development work in the area of dielectrics—ceramics, glass, porcelain, plastics, and even silicon IC-type construction. Further component development will seek to reduce device size by exploiting existing chemistries, such as electrolytics, film, and ceramics, while lowering equivalent series resistance (ESR) and improving reliability.

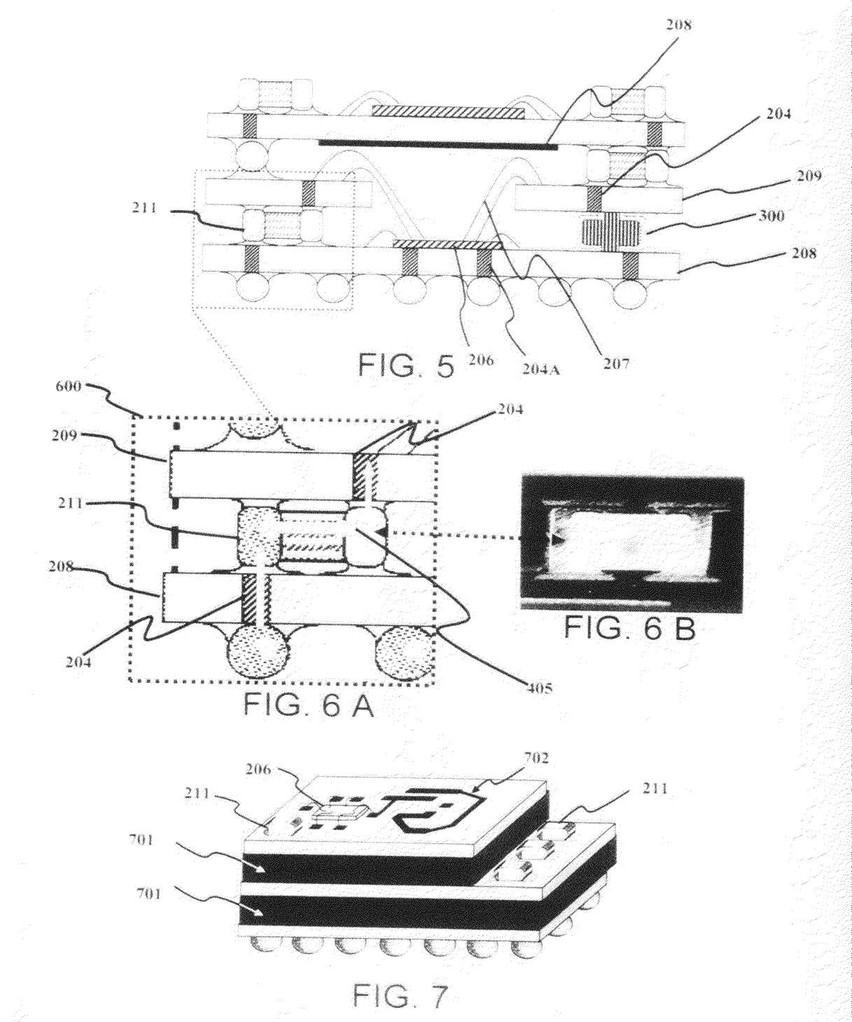

FIG. 6A demonstrates how at least a passive component 211 may be used for this application. Electrical vias 204 connecting from the bottom of the substrate 208 connect using solder alloys 205 through said passive component 211 allowing the electrical or high frequency energy to be transformed, stored, distorted, dissipated or by some manner manipulated 405 by said passive component 211 to the next level substrate 209 to another said via 204 using at least an attachment technique such as solder 205. FIG. 6B is a crossectional micrograph of at least an embodiment depicting a chip capacitor connected with solder. FIG. 5 and illustrates how interconnecting device 300 and said passive component 211 may be used to stabilize a complex 3D structure. Here, the passive component serves as the means to transform electrical signals to the upper substrates, whereas the interconnecting component 300 serves as a damper for thermal mismatch stresses. The IC 206 or active component may be mounted on the top of the bottom substrate 208 where thermal vias 204 may dissipate the heat through the bottom substrate. The IC 206 may further be attached using wirebonds 207 through a cavity to the middle substrate 209 allowing for more input/outputs to said IC 206, consequently reducing the overall size of the high frequency device. Said inventive method of hybrid mechanical and electrical interconnections allows improved reliability, low effective series resistance (ESR) and low self-resonant frequency (SRF). Low ESR and SRF means overall low losses and high Q, resulting in better performance for filters and matching networks. Low SRF will minimize unwanted responses in filters and matching networks, which is highly desirable in coupling and decoupling applications.

High frequency packaging or applied electromagnetic engineering, is the design of guided-wave structures such as waveguides and transmission lines, transitions between different types of transmission lines, and antennae all require control of the underlying electromagnetic fields. Power amplifier combiners and transmission line components are challenging when packaged under a single compact device. Fields are usually contained in the art by including metal planes 208 and metal vias 204 trough the structure as seen in FIG. 2 and FIG. 5. In order to create shielding and control of said high frequency fields, the present technology allows for a substantial ease in the control of said high frequency energy coming form the high frequency IC 206 or any input antennae in the circuit. By creating grounds, metal planes 208, metal vias 204, the interconnecting devises 300 and the passive devises 211 the 3D structure as a whole becomes the means for signal input, control/manipulation, transformation and output. In FIG. 7 for example, the disclosed technology allows for microstrip, transmission lines, couplers and other high frequency input/output means 702, including high frequency ICs 206, passive networks 211, to be separated from the main controller and amplifier circuits. The networks are disposed in the inside of the structure 701 between any of the substrates 210, 208, 209. This separation of components by levels in the 3D structure allows for better noise cancellation and noise management of the high frequency circuit.

In wireless products, it is not unusual for engineers to go through two or three design revisions, therefore the faster they test components, make changes, the faster they can get to market. High frequency packaging is very dimension and structure specific. Any minor change in the physical design proportions and parameters allow for distortion in signals and input values not counted for in the models. Failures due to inadequate thermal design may be manifested as components running too hot or too cold. This will cause operational parameters to drift beyond specifications. Operation at higher frequencies requires predicting with accuracy the performance of the complete circuit. As expected, tradeoffs are required, especially at the smallest and largest sizes of devices. Rapid rework of high frequency circuits has been a major impediment for 3D structures, both in laboratory device and production test devices.

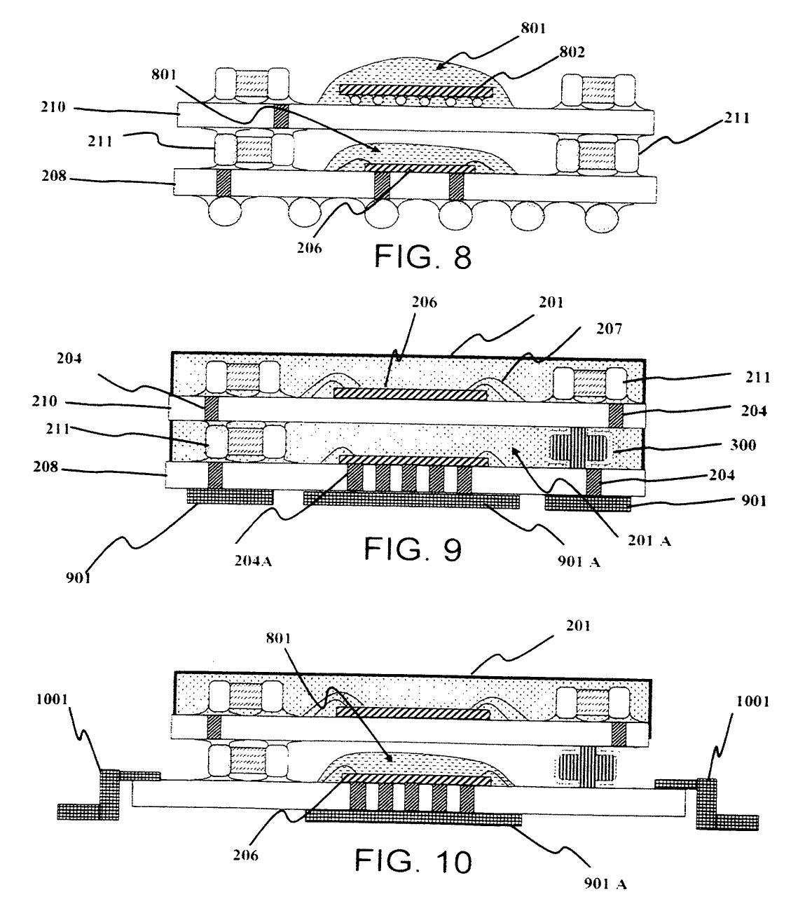

The disclosed technology allows for the rework process of components, for engineering and prototype, to be quickly removed from the top substrate without damaging the interconnections between the substrates 210, 208, 209 and without causing destructive damage. This may be achieved by “wetting” the bottom side of the top substrate 210 in FIG. 8 or FIG. 10 with low temperature solder alloy and the top side of the bottom substrate 208 with a high temperature alloy solders. The SMT components may later be disposed on the solder alloys and reflowed at the higher temperature. Because of the difference in the melting temperature of the top solder and the bottom solder, by raising the overall temperature of the device, it allows for the removal of the top substrate 210. Now, rework and tuning to the IC 405 or any other circuits in the bottom substrate of the structure may be performed. This process is called in the high frequency art as “tuning” the components to a final frequency. Once the rework is complete, the top substrate 210 may be reflowed again at the lower temperature and the 3D structure is achieved again. The rework could not have been made if the connections between substrates were made wholly of one temperature solder since once solder is reflowed the monolithic structure is dissolved. Notice that in the embodiment FIG. 8 there is no interconnecting component 300 incorporated as part of the 3D structure. It is only upon the necessity of a mechanical damper that a combination of interconnection components 300 and passives 211 will be used as person skilled in the art desires for flatness and integrity.

FIG. 8 depicts two types of IC's disposed upon the aforementioned substrates. On the top substrate 210 a flipchip 809 active component is disposed, further disposed upon said flipchip 809 is a removable globtop 801 encapsulation type material. On the bottom substrate 208 a non-flipchip devise may be placed upon said substrate, and further disposed upon said active chip 208 may be a removable globtop 801 encapsulation type material. Said globtop material may be selected from the group consisting of polymers, silicones, adhesives, waxes, acrylics and polyacrylates, epoxy resins, polybutadiene, polycarbonate (PC), polypropylene (PP), polyurethane (PUR), vinyl, and polyvinyl chloride (PVC). Equivalent materials based on ceramic or inorganic cements are often used in high temperature applications. The preferred compounds comprise but are not limited to Hitachi CEL9240HF-10 and/or CEL9770HF-10 and the Sumitomo G760Y. The preferred solder pastes comprise, but are not limited to: 5.1 SAC from Indium Corp. and the Sn/Sb 95CR32 from Loctite Corp.

Thermal performance failures can arise due to incorrect design of thermal paths in an electronic assembly. This includes incorrect conductivity and surface emissivity of individual components as well as incorrect convective and conductive paths for heat transfer. Thermal overstress failures are a result of heating a component beyond critical temperatures such as the glass-transition temperature, melting point, fictive point, or flash point. FIG. 9 depicts an embodiment where the IC on the bottom substrate 208 is attached to thermal vias 204A through said substrate. Both the heat dissipation, and the input and output signals to the IC's in the package may be accomplished through what is known in the art as “land grid array” pads 901. The heat generated from the IC may be transferred to the Printed Circuit Board (PCB) through copper or similar high conductive metal vias 204A to a metallized pad on the bottom of the package 901A. The package in FIG. 9 uses the advantages of the described technology where the input signals coming from the bottom substrate are in some form transformed or manipulated to the next substrate 210 though via 204 which in turn have some effect to in the top IC 206 or any circuit mounted on the top substrate 210. The disclosed technology allows for the heat of the top IC 206 to be dissipated in radiation thought the control of the emissivity of the top encapsulation material 201, (a black or plated encapsulation polymer is preferred) or though conduction thought the to substrate 210 as the heat travels along the substrates to the sides of the package.

For power-handling components like resistors, size reduction amounts to raising the current-handling ability of a given device. That typically requires improvements in material composition and packaging to dissipate more heat in a small area—the same challenge faced by power semiconductors and high-speed processors IC's 206. FIG. 10 depicts a combination embodiment of the described technology where the inputs/outputs may be accomplished though what is known in the art as a “lead frame” attach 1001. The heat of the bottom IC may be accomplished in the same way as in FIG. 9 though vias and finally to a land grid array pad on the bottom of IC 206. Encapsulation glob top 801 or underfill materials 201A are often used to encapsulate or protect the semiconductor IC 206 from oxidation and impurities. Usually a silicone based underfill is used, the main purpose of the underfill or globe top material is to mechanically assist in the TCE mismatch between the IC and the PCB board and to aid in the heat transfer of the heat from the semiconductor component to the rest of the package by transferring the heat through a medium other than air.

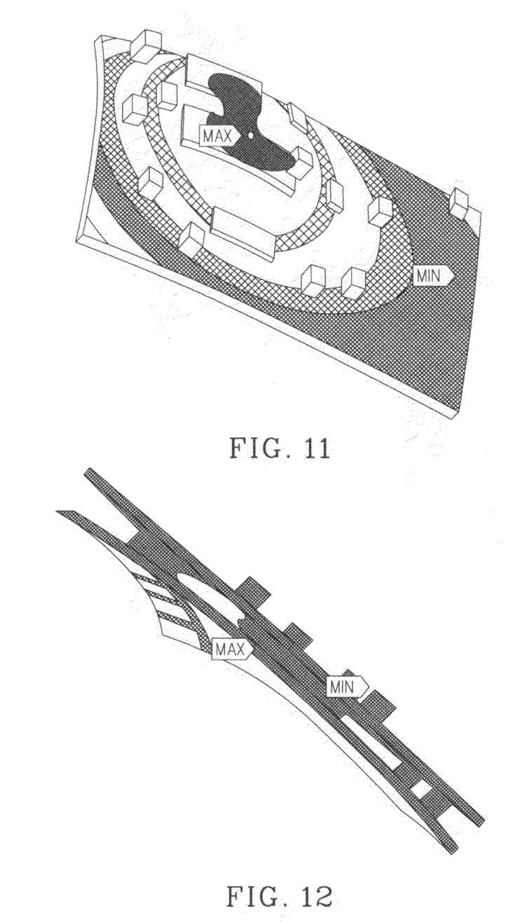

Recently, much work has been undertaken to properly characterize the effects of packaging. This concept is being extended to the layout surrounding the components on 3D Multi-chip modules (MCMs), layered board techniques and passives-in-package (PiP) devices. Adequate design checks require proper analysis for thermal stress, and should include conductive, convective, and radiative heat paths. Integrated modules have to be focused on manufacturability, to reduce cost while implementing the performance enhancements required for new high-speed/high-frequency applications. Two approaches are used to deal with the additional parasitic reactance of power devices—keeping the size as small as possible using materials with high thermal performance, and accurately modeling the component so compensation for its effects can be designed into other portions of the circuit. FIGS. 11 and 12 depict models of distortioned substrates before the implementation of design rules and applying the concepts of the described technology to the application of 3D multi-substrate devises.

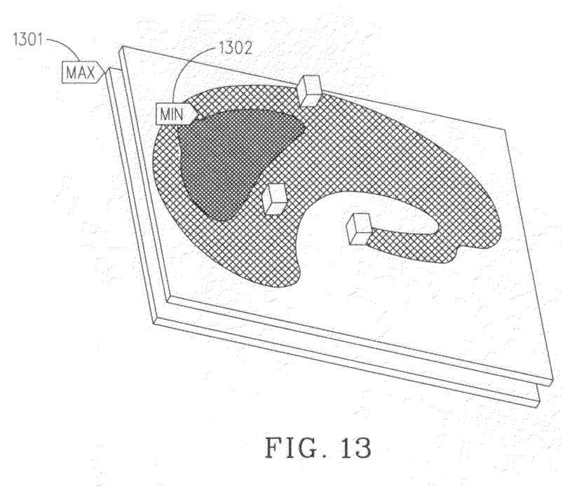

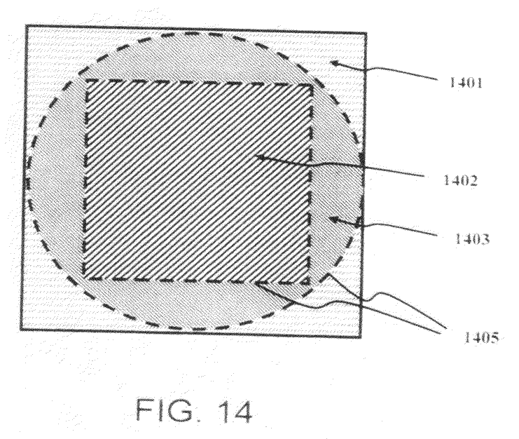

FIG. 13 is the model of a balanced package where 1301 is the maximum stress concentration and deformation due to thermal loads. The balanced model was accomplished by moving the heat generating components out of zone 1401 depicted in FIG. 14, and placing them in the interior of the package in zone 1402. 1403 is an intermediate stress zone where hot components are most likely undesirable. Furthermore interconnectors 300 may be placed strategically at the edge of the package in zone 1401 to mechanically react to the thermal loads; hence the balanced package now survives deformation. A person of ordinary skill in the art of modeling high frequency packages may accommodate the components to accomplish a similar result for the same purpose of balancing the devise using different parameters. Notice that the borders 1405 between the different zones are approximate; there are no specified values or distances.

Reliability specifications require testing of the products, including the expected accelerated life tests at elevated temperatures along with vibration and electrical stresses. High power applications require materials and testing to handle high voltages, high DC currents, high frequency currents, high temperatures and thermal cycling. Like the rest of high frequency electronics, there is a divergence in emphasis—small size and low cost vs. highest performance. In handsets impedance matching techniques require directional couplers to sample input or output signals and inject correction signals. Consistent performance at reasonable cost is the key.

Reliability experiments where performed using the disclosed technology in order to validate the models described in FIGS. 13 and 14, also to demonstrate the actual reduction to practice and possession of technology and its reliability. The experiments where performed in a 7×7 cm test vehicle using 0.1 mm thick laminate substrates and mechanical daisy chain SMDs (Surface Mount Devices) (48 SMD/module). DC continuity test was performed to verify and demonstrate electrical and reliability performance before and after of reliability tests. For the solderability test and methodology, refer to IPC/EIA J-STD-003A—Test E Surface Mount Process Simulation Test. This test method was designed to provide a means of determining the solderability of device package terminations that are intended to be joined to another surface using Pb-free solder for the attachment. Test method—Preheat Temperature: 150-170° C. —Preheat Time: 50-70 second—Soak Temperature: 215-230° C. —Soak Time: 50-70 seconds. 5. Temperature Cycle and Cross section (Refer to JESD 22-A104-A). The result was 100(%) Yield.

Another reliability test was performed to determine the ability of component and solder paste interconnections to withstand mechanical stresses induced by alternating high and low temperature extremes. Permanent changes in electrical and/or physical characteristics can result from this mechanical stress. Cross section and SEM were added for check solder joint cracking. Test method—Machine: BAMCO #5, —Temperature: −40° C. to +100° C. —Transfer time: 5 minutes—Dwell Time: 15 minutes—Number of Cycle 1000 cycles. The result was 100(%) Yield.

It will be appreciated by those skilled in the art that changes could be made to the embodiments described above without departing from the broad inventive concept thereof. It is understood, therefore, that this technology is not limited to the particular embodiments disclosed, but it is intended to cover modifications within the spirit and scope of the present technology.

What is claimed is:

1. A method of manufacturing a mechanically adapting interconnecting device for multi-substrate packages comprising:
placing a metal laminate on each side of a polymer composite;
forming a channel in said metal laminate; and
metallizing said laminate to create a metal connection inside said channel.

2. The method of claim 1, further comprising dicing with an abrasive dicing wheel to create a trough within said metallized channels to create a dielectric spacing.

3. The method of claim 2, further comprising dicing said interconnecting device to mimic the dimensions of a passive component.

4. The method of claim 2, further comprising dicing said interconnecting device to the dimension that will give enough space to accommodate integrated circuits and other passive components.

5. An apparatus, comprising:
a substrate interconnecting device, said substrate interconnecting device comprising:
a polymer composite with a metal laminate on each side of said polymer composite, said metal laminate including a metallized channel with a metal connection within said metallized channel interconnecting of a plurality of substrates.

6. The apparatus of claim 5, further comprising a trough within said metallized channels to create a dielectric spacing.

7. The apparatus of claim 6, wherein said trough mimics the dimensions of a passive component.

8. The apparatus of claim 6, wherein said interconnecting device is used to mechanically adjust for thermal and mechanical variations.
